(19) United States
(12) Patent Application Publication
(10) Pub. No.: US 2024/0395459 A1
(43) Pub. Date: Nov. 28, 2024

(54) STRONTIUM OXIDE INTERLAYERS FOR IMPROVED ELECTRICAL DEVICE PERFORMANCE

(71) Applicants: Ruben Waldman, Berkeley, CA (US); Randall J. Higuchi, SANTA CLARA, CA (US); Daniel Lee, NEWARK, CA (US); Charlene Chen, CUPERTINO, CA (US); Chiliang Chen, SUNNYVALE, CA (US)

(72) Inventors: Ruben Waldman, Berkeley, CA (US); Randall J. Higuchi, SANTA CLARA, CA (US); Daniel Lee, NEWARK, CA (US); Charlene Chen, CUPERTINO, CA (US); Chiliang Chen, SUNNYVALE, CA (US)

(21) Appl. No.: 18/674,450

(22) Filed: May 24, 2024

Related U.S. Application Data
(60) Provisional application No. 63/504,688, filed on May 26, 2023.

(51) Int. Cl. H01G 4/10; H01G 4/12

(52) U.S. Cl. CPC H01G 4/10; H01G 4/1236; H01L 28/65

(57) ABSTRACT

The disclosed and claimed subject matter relates to a capacitor having an interlayer comprising a strontium oxide material. The interlayer is formed adjacent to the dielectric layer. The interlayer is incorporated in a capacitor stack and is preferably deposited using atomic layer deposition.

### CROSS-REFERENCE TO RELATED APPLICATIONS

This application claims priority to U.S. Provisional Patent application No. 63/504,688 filed on May 26, 2023, which is hereby incorporated by reference.

### FIELD

The disclosed and claimed subject matter relates generally to interlayers deposited using vapor techniques, including atomic layer deposition (ALD). More specifically, the disclosed and claimed subject matter relates to capacitors having thin film interlayers that contain strontium and methods for preparing and depositing these materials. Significantly, devices fabricated with these materials exhibit improved leakage and capacitance properties.

### BACKGROUND

Few-nanometer films of high-k dielectrics, including ZrO₂, HfO₂ and HfₓZr₁₋ₓO₂ have different functional properties based on the thickness and crystal structure of the film. The high-k tetragonal crystal phase of ZrO₂, is difficult to crystallize in few-nanometer films, and the leakage current through the device scales strongly with thickness. Leakage and capacitance are also strongly influenced by the interfacial states that are formed 1) when the dielectric layer is grown on a conductive electrode material (e.g., TiN) called bottom electrode layer (BEL) and 2) when a conductive electrode material (e.g., TiN) is grown on top of the dielectric layer, called top electrode layer (TEL).

The performance of the interfaces between the dielectric and both electrodes is a function of processing conditions during device fabrication including but not limited to: 1) the temperature of each deposition step; 2) intentional dopants or unintentional impurities incorporated into the layers through the deposition; 3) the local crystallization, grain size, and surface roughness of each layer; and 4) the temperature and duration of additional heat treatment annealing conducted between the deposition of each layer or after all layers are deposited.

Known electrode-dielectric-electrode stacks seek to reduce leakage current and equivalent oxide thickness (EOT, i.e., increase capacitance) for thinner dielectric layers. In ZrO₂ stacks an Al₂O₃ layer is often used (termed ZAZ stack) to interrupt crystalline domains and break continuous grain boundaries which traverse the film between top and bottom electrodes. These grain boundaries present charge transport pathways and interrupting them with a ZAZ configuration reduces leakage current. Beyond grain boundary engineering, additional metal oxide (additional i.e., beyond the major metal specie in the dielectric stack) can be used to stabilize dielectric crystalline phases with higher k. Without the addition of these dopants, it can be difficult to stabilize the desired phase in the low thickness films of interest.

A further device in the prior art (US2021265458 AA) relates to the use of interfacial control layer (ICL) to improve device performance. This reference refers only to the use of Al₂O₃ or doped-Al₂O₃.

### SUMMARY

In a first main aspect, a capacitor is provided. The capacitor comprising: a bottom electrode; a top electrode above the bottom electrode; a dielectric film between the bottom electrode and the top electrode; and a SrO_{X} film that forms an interlayer between the top electrode and the dielectric film, wherein x is an integer from 1 to 3.

In a further aspect of the first main aspect, the dielectric film comprises ZrO₂, HfO₂, an alloy of ZrO₂ and HfO₂ (i.e., HZO), or combinations thereof. In a further aspect of the first main aspect, the SrOx film has a thickness ranging from about 0.1 Å to about 10.0 Å. In a further aspect of the first main aspect, a further interlayer is provided between the bottom electrode and the dielectric film; and wherein the further interlayer comprises an oxide of a metal element. In a further aspect of the first main aspect, the bottom electrode directly contacts the dielectric film. In a further aspect of the first main aspect, the bottom electrode comprises a metal nitride represented by MN, M is a metal element, and N is nitrogen. In a further aspect of the first main aspect, the further interlayer comprises a metal oxynitride represented by M′OxNy, M is a metal element, M′ is a metal element, N is nitrogen, and O is oxygen. In a further aspect of the first main aspect, the bottom electrode comprises TiN. In a further aspect of the first main aspect, M is Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, or U. In a further aspect of the first main aspect, M′ is H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Ti, Pb, Bi, Po, Fr, Ra, Ac, Th, Pa, or U. In a further aspect of the first main aspect, the dielectric film has a thickness of about 30 Å to about 100 Å; and wherein the SrO_{X} film has a thickness of about 0.1 Å to about 10.0 Å, more preferably from about 0.5 Å to about 5.0 Å. In a further aspect of the first main aspect, the top electrode directly contacts a top surface of the SrOx film, and the dielectric film directly contacts a bottom surface of the SrOx film. In a further aspect of the first main aspect, the top electrode comprises TiN, MoN, CoN, TaN, TiAlN, TaAlN, W, Ru, RuO₂, SrRuO₃, Ir, IrO₂, Pt, PtO, (Ba,Sr)RuO₃ (BSRO), CaRuO₃ (CRO), (La,Sr)CoO₃ (LSCO), or a combination thereof. In a further aspect of the first main aspect, the dielectric film is doped with a metal, wherein the metal is chosen from the group consisting of: Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U.

In a second main aspect, a semiconductor device is provided. The semiconductor device comprising: a substrate; a gate structure on the substrate; a first source/drain region and a second source/drain region, both arranged in upper portions of the substrate; and a capacitor on the substrate, the capacitor comprising a bottom electrode, a top electrode, a dielectric film between the bottom electrode and the top electrode, and a SrOx film between the top electrode and the dielectric film, the bottom electrode being electrically connected to the first source/drain region, the top electrode being over the bottom electrode.

In a further aspect of the second main aspect, the SrOx film has a thickness of between about 0.1 Å and about 10 Å, more preferably from about 0.5 Å to about 5.0 Å. In a further aspect of the second main aspect, the bottom electrode comprises a metal nitride represented by MN, wherein M is a metal element, and N is nitrogen. In a further aspect of the second main aspect, M is H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, or U. In a further aspect of the second main aspect, a metal oxynitride interlayer is present between the bottom electrode and the dielectric film; and the metal nitride is represented by MxOyNz, 0<x≤2, 0<y≤2, and 0<z≤4. In a further aspect of the second main aspect, the top electrode directly contacts a top surface of the SrOx film, and the dielectric film directly contacts a bottom surface of the SrOx film.

In a third main aspect, a method of fabricating a capacitor is provided. The method of fabricating a capacitor comprising: forming a bottom electrode; forming a dielectric film; forming a SrOx layer on the dielectric film; and forming a top electrode on the SrO_{X} layer, wherein X is an integer from 1 to 3.

In a further aspect of the third main aspect, the step of forming the SrOx layer on the dielectric film further comprises a step of performing a heat treatment on the dielectric film and the SrOx layer. In a further aspect of the third main aspect, the forming of the SrOx layer on the dielectric film comprises: a. arranging a substrate in a reaction chamber and supplying a metal precursor into the reaction chamber; b. performing a first purging step for removing any excess portion of the introduced metal precursor; c. supplying an oxygen-bearing source into the reaction chamber; and d. performing a second purging for removing the oxygen source that has not reacted, along with any evolved chemical species formed by the reaction of the oxygen-bearing gas with the substrate. In a further aspect of the third main aspect, the metal precursor is represented by MRx, wherein M is a metal element and R is an organic ligand; and x is in a range of 0<x≤6. In a further aspect of the third main aspect, M is Sr; and wherein R comprises at least one of a C1-C10 alkyl group, a C2-C10 alkenyl group, a carbonyl group (C═O), a halide, a C6-C10 aryl group, a C6-C10 cycloalkyl group, a C6-C10 cycloalkenyl group, (C═O)R (where R is hydrogen or a C1-C10 alkyl group), a C1-C10 alkoxy group, a C1-C10 amidinate, a C1-C10 alkylamide, a C1-C10 alkylimide, N(Q)(Q′) (where Q and Q′ are each independently a C1-C10 alkyl group or hydrogen), Q(C═O)CN (where Q is hydrogen or a C1-C10 alkyl group), and a C1-C10 β-diketonate. In a further aspect of the third main aspect, M is Sr, and wherein the metal precursor is chose from the group consisting of: Sr(i-Pr₃Cp)₂, Sr(t-Bu₃Cp)₂, Sr(Me₅Cp)₂, Sr(n-PrMe₄Cp)₂, bis(2,5-di-iso-propylpyrrolyl)strontium, bis(2,5-di-tert-butylpyrrolyl)strontium, bis(2,4,5-tri-tert-butylimidazolyl)strontium, bis(2,2-dimethyl-5-(dimethylaminoethyl-imino)-3-hexanonato-N,O,N′)strontium, bis(2,2-dimethyl-5-(dimethylaminoethyl-imino)-3-hexanonato-N,O,N′)strontium and their adducts with neutral coordinating ligands.

In a fourth main aspect, a capacitor is provided. The capacitor comprising: a bottom electrode; a top electrode over the bottom electrode; a dielectric film between the bottom electrode and the top electrode; and a SrOx layer between the top electrode and the dielectric film, wherein the SrOx layer has a thickness of about 0.1 Å to about 10.0 Å, more preferably from about 0.5 Å to about 5.0 Å.

A semiconductor device comprising the capacitor of the fourth main aspect. An electronic device comprising: the capacitor of the fourth main aspect.

In a fifth main aspect, a method of forming a strontium oxide layer is provided. The method of forming a strontium oxide layer comprising: forming a strontium oxide material on a dielectric material using an atomic layer deposition process, wherein the atomic layer deposition uses a strontium precursor with an oxygen source; annealing the dielectric material, comprising the top layer of strontium oxide material to form the strontium oxide layer.

In a further aspect of the fifth main aspect, the strontium precursor is represented by MRx, wherein M is Sr and R is an organic ligand; and x is in a range of 0<x≤6. In a further aspect of the fifth main aspect, R comprises at least one of a C1-C10 alkyl group, a C2-C10 alkenyl group, a carbonyl group (C═O), a halide, a C6-C10 aryl group, a C6-C10 cycloalkyl group, a C6-C10 cycloalkenyl group, (C═O)R (where R is hydrogen or a C1-C10 alkyl group), a C1-C10 alkoxy group, a C1-C10 amidinate, a C1-C10 alkylamide, a C1-C10 alkylimide, N(Q)(Q′) (where Q and Q′ are each independently a C1-C10 alkyl group or hydrogen), Q(C═O)CN (where Q is hydrogen or a C1-C10 alkyl group), and a C1-C10 β-diketonate. In a further aspect of the fifth main aspect, M is Sr, and wherein the metal precursor is chose from the group consisting of: Sr(i-Pr₃Cp)₂, Sr(t-Bu₃Cp)₂, Sr(Me₅Cp)₂, Sr(n-PrMe₄Cp)₂, bis(2,5-di-iso-propylpyrrolyl)strontium, bis(2,5-di-tert-butylpyrrolyl)strontium, bis(2,4,5-tri-tert-butylimidazolyl)strontium, bis(2,2-dimethyl-5-(dimethylaminoethyl-imino)-3-hexanonato-N,O,N′)strontium, bis(2,2-dimethyl-5-(dimethylaminoethyl-imino)-3-hexanonato-N,O,N′)strontium and their adducts with neutral coordinating ligands.

In a sixth main aspect, a method of forming a strontium oxide layer is provided. The method of forming a strontium oxide layer, comprising: chemisorbing a strontium precursor on a dielectric material in an atomic layer deposition process; reacting an oxygen source with the chemisorbed strontium precursor; repeating a cycle of chemisorbing the strontium precursor and reacting the oxygen source with the chemisorbed strontium precursor for a number of cycles to form a strontium oxide material on the dielectric material; annealing the strontium oxide material to form the strontium oxide layer.

In a further aspect of the sixth main aspect, the step of repeating the cycle of chemisorbing the strontium precursor and reacting the oxygen source with the chemisorbed strontium precursor for a pre-determined number of cycles is performed until the desired thickness of the strontium oxide material is formed. In a further aspect of the fifth main aspect, repeating the cycle of chemisorbing the strontium precursor and reacting the oxygen source with the chemisorbed first strontium precursor until a desired thickness of the strontium oxide material is formed comprises a desired thickness of at least approximately 1.0 Å and no more than 10.0 Å. In a further aspect of the fifth main aspect, the step of repeating the cycle of chemisorbing the strontium precursor and reacting the oxygen source with the chemisorbed strontium precursor for between one and four cycles to form a desired thickness of the strontium oxide material.

In a seventh main aspect, a method of forming a capacitor is provided. The method of forming a capacitor comprising: a. forming a first electrode; b. forming a dielectric material on the first electrode c. forming a strontium oxide material on the dielectric material using an atomic layer deposition process using a strontium precursor as a first precursor and ozone as a second precursor; d. annealing the bottom electrode, the dielectric material, and the strontium oxide material thereby forming a strontium oxide layer; and e. forming a second electrode on the strontium oxide layer.

In a further aspect of the seventh main aspect, forming a strontium oxide material on the dielectric material using an atomic layer deposition process using a strontium precursor as a first precursor and ozone as a second precursor comprises: chemisorbing the strontium precursor on the dielectric material; and reacting the ozone with the chemisorbed strontium precursor.

In a further aspect of the seventh main aspect, annealing the bottom electrode the dielectric material and the strontium oxide material is conducted at a temperature between 100 and 600 degrees Celsius for a time period of from 1 minute to about 100 minutes. In a further aspect of the sixth main aspect, further comprising patterning the capacitor into a capacitor array.

In an eighth main aspect, an integrated circuit device is provided. The integrated circuit device, comprising: a titanium nitride electrode; a dielectric layer overlying the titanium nitride electrode; a strontium oxide interface overlying the dielectric layer; and wherein a strontium oxide interface interposed between the dielectric layer and a further electrode; wherein the strontium oxide interface is formed using a method comprising: performing an atomic layer deposition process using a strontium precursor as a first precursor and ozone as a second precursor to form the strontium oxide material on the dielectric layer; and annealing the strontium oxide material to form the strontium oxide interface.

In a further aspect of the eighth main aspect, annealing the bottom electrode and the strontium oxide material to form the strontium oxide interface comprises performing a rapid thermal anneal in an environment comprising nitrogen or argon.

In a ninth main aspect, a memory device is provided. The memory device comprising: an array of memory cells, the memory cells comprising an access transistor and a capacitor, wherein at least one of the capacitors comprises: a bottom electrode; a top electrode; a dielectric layer disposed between the bottom electrode and the top electrode; a strontium oxide film interposed between the dielectric layer and the top electrode; and wherein the strontium oxide interface is formed using a method comprising: forming the strontium oxide film on the dielectric layer by atomic layer deposition with ozone; and annealing the strontium oxide film to form a strontium oxide interfacial layer.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates a capacitor stack in accordance with an embodiment of the instant disclosure;

FIG. 2 illustrates an alternative embodiment of a capacitor stack disclosed herein;

FIG. 3 illustrates an embodiment of a process for depositing an example of the strontium oxide interlayer disclosed herein on a dielectric;

FIG. 4 illustrates another embodiment of a process for depositing a strontium oxide interlayer;

FIG. 5 illustrates leakage current versus equivalent oxide thickness for strontium interlayers of different thicknesses; and

FIG. 6 illustrates leakage current versus equivalent oxide thickness comparing no interlayer, an aluminum oxide interlayer, and a strontium oxide interlayer.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

For purposes of this disclosure and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal silicide film, a metal carbide film and the like.

As used herein, the terms “elemental metal,” “elemental metal film” and “pure metal film” are used interchangeably and refer to a film which consists of, or consists essentially of, pure metal. For example, an elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. However, a film comprising an elemental metal is distinguished from binary films including a metal and a non-metal (e.g., C, N, O) and ternary films including a metal and two non-metals (e.g., C, N, O), though, a film comprising elemental metal may include some amount of impurities. Unless context dictates otherwise, the term “metal film” shall be interpreted to mean an elemental metal film.

As used herein, the terms “deposition process” and “thermally depositing” are used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al., J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. The substituents may be any of the acyclic alkyl groups described herein. As mentioned herein the cyclic alkyl groups may have any of the acyclic alkyl groups as substituent. These alkyl moieties may be substituted or unsubstituted.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

The problem solved by this disclosure is that ultra-thin high-k capacitors are compromised in their DRAM performance by high leakage current and high equivalent oxide thickness (EOT, a measurement of capacitance and ‘k’).

The present disclosure demonstrates an improvement in high-k capacitor performance when a few-cycle strontium oxide (SrOx, wherein X is an integer from 1 to 3) layer is introduced between the dielectric layer and the top electrode layer. Whereas strontium oxide (SrOx) has been explored as a dopant material in the prior art, in the present disclosure the SrOx layer improves device performance when implemented as an interlayer between the dielectric and top electrode. The electronic performance of devices fabricated with the SrOx layers show lower leakage current and EOT compared to control devices fabricated without these layers. Furthermore, SrOx ICLs of 2 Å thickness are shown to outperform Al₂O₃ ICLs of comparable thickness in leakage. Of particular note is that the SrOx ICL yields an improved capacitance (lower EOT) across all devices tested. In the prior art, Al₂O₃ and doped-Al₂O₃ only improve leakage, and in fact are detrimental to the capacitance.

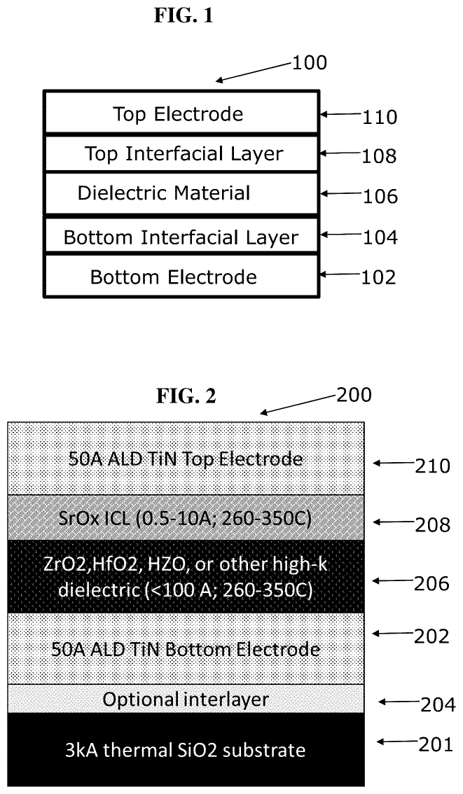

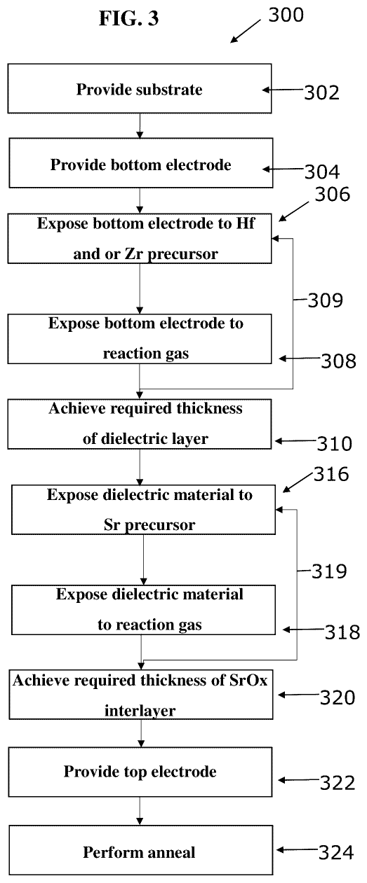

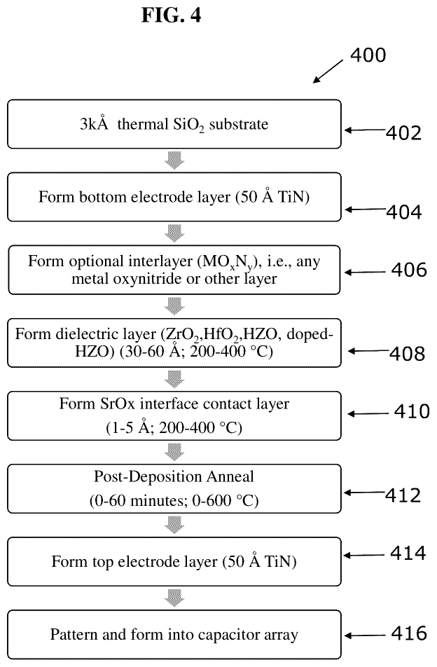

FIG. 1 illustrates a capacitor stack in accordance with an embodiment of the instant disclosure. FIG. 2 illustrates an alternative embodiment of a capacitor stack disclosed herein. FIGS. 3 and 4 illustrate process flow for integration of SrOx ICL between dielectric and top electrode.

In two examples provided below, MIMCAPs comprised of a TiN—ZrO₂—TiN stack showed reduction in leakage and EOT with the inclusion of a thin SrOx layer between the dielectric layer and TiN top electrode layer. At a 260 C deposition temperature, a SrOx ICL of approximately 2 Å thickness measurably outperforms an equivalent device where a known AlOx ICL of approximately 2 Å is used. A notable feature relates to the improved performance of the SrOx ICL over the AlOx ICL at comparable device thicknesses. Furthermore, the SrOx ICL shows a clear improvement in both leakage and capacitance of the film Therefore, the present design offers a better performing capacitor for integrated circuits than prior devices.

The preferred range of thicknesses for this strontium oxide film is approximately 0.2 nm to approximately 20 nm and is more preferably approximately 0.2 nm to 10 nm. It is also preferable that the materials form films having a thickness of approximately 10 nm and less. In some embodiments it is preferable that the materials form films having a thickness of approximately 5 nm and less.

As discussed above, however, preferred and/or desired thicknesses will change depending on specific application. Thus, as noted previously, in some embodiments the interlayer will be approximately 20 nm or less. In a further aspect the interlayer will be approximately 15 nm or less. In a further aspect, the interlayer will be approximately 10 nm or less. In a further aspect, the interlayer will be approximately 5 nm or less. In a further aspect, the interlayer is approximately 3 nm or less. In a further aspect, the interlayer is approximately 1 nm or less. In a further aspect, the interlayer is approximately 0.5 nm or less. In a further aspect, the interlayer is approximately 0.2 nm or less. In a further aspect, the interlayer has properties of reducing leakage when between approximately 0.005 nm to approximately 1 nm. In a further aspect, the interlayer is between approximately 0.01 nm to approximately 0.5 nm. In a further aspect, the thin films interlayer is between approximately 0.05 nm to approximately 0.4 nm.

### III. Methods for Preparing and Depositing a Strontium Oxide Interlayer

As noted above, in another aspect the disclosed and claimed subject matter is directed to a process for preparing and/or depositing the interlayers disclosed herein. In this process, the disclosed and claimed interlayers are prepared by iterative depositions and purges (i) of a metallocene precursor and (ii) a reactant.

### A. Strontium Precursors

As noted above, the strontium oxide materials are derived from advanced metallocene precursors. The strontium precursors should have sufficient vapor pressure and stable enough to be delivered into the reaction chamber, and may have a formula of SrX₂Yₙ wherein X is a monoanionic ligand selected from the group consisting of substituted cyclopentadienyl, substituted pyrollyl, substituted imidazolyl, polydentate beta-ketoiminate, polydentate diketiminate, Y is a neutral coordinating ligand, n is 0, 1, 2, 3, 4. Examples of metal-containing precursors include, but not limited to, Sr(i-Pr₃Cp)₂, Sr(t-Bu₃Cp)₂, Sr(Me₅Cp)₂, Sr(n-PrMe₄Cp)₂, bis(2,5-di-iso-propylpyrrolyl)strontium, bis(2,5-di-tert-butylpyrrolyl)strontium, bis(2,4,5-tri-tert-butylimidazolyl)strontium, bis(2,2-dimethyl-5-(dimethylaminoethyl-imino)-3-hexanonato-N,O,N′)strontium, bis(2,2-dimethyl-5-(dimethylaminoethyl-imino)-3-hexanonato-N,O,N′)strontium and their adducts with neutral coordinating ligands. In a preferred embodiment, the strontium precursor is Sr(i-Pr₃Cp)₂.

In general, suitable precursors are able to be deposited between approximately 200° C. and approximately 570° C. depending on the composition of the material, substrate, and reactor design, among other factors. A preferred temperature is approximately 280° C. (or generally between approximately 250° C. and approximately 400° C.), and the preferred temperature range is below approximately 450° C. and more preferably below approximately 340° C. However, those skilled in the art should recognize that other temperatures may be possible depending on the specific precursor used and that such precursors also fall within the scope of the disclosed and claimed subject matter. It should further be noted that with certain precursors besides the ones listed here, decomposition of the precursor can occur within the temperature range described. Decomposition products, in particular carbon and organic species, can become incorporated in the deposited strontium oxide material.

### B. Reactant

The reactant is a reaction gas containing one or more of oxygen (e.g., ozone, elemental oxygen, molecular oxygen/O₂), water, hydrogen peroxide and nitrous oxide. In one embodiment, ozone is a preferred reactant gas. In another embodiment, water is a preferred reactant gas.

### C. Process Steps

FIG. 3 illustrates an embodiment of a process for preparing and depositing the strontium oxide interlayer descried herein. As illustrated, substrate 302 undergoes an ALD cycle in which substrate 302 is exposed to vapor to form and deposit a bottom electrode. material as thin film layer 300. As illustrated, substrate 302 undergoes an ALD cycle in which substrate 302 is exposed to vapor to form and deposit a bottom electrode. material as thin film layer 300. For example, energy can subsequently be applied to the material by, but not limited to, thermal, plasma, pulsed plasma, helicon plasma, high density plasma, inductively coupled plasma, X-ray, e-beam, photon, remote plasma methods, and combinations thereof.

The constituents of vapor change during ALD cycle. In particular, substrate is alternatingly exposed to metallocene precursor followed by a purge and then exposed to reactant followed by another purge. This process continues until a desired thickness for layer is obtained. Although ALD is a preferred vapor deposition technique, any suitable vapor phase deposition technique can be utilized, such as CVD or pulsed CVD. Thus, for example an ALD cycle could be replaced by a CVD process in which metallocene precursor and reactant are provided as a mixture in vapor and provided simultaneously to substrate.

The substrate 302 on which the bottom electrode 304 is formed as layer can include any suitable material, including semiconducting materials like silicon, germanium, III-V materials, transition metal dichalcogenides, and mixtures thereof, metals and conductive ceramics like titanium nitride, titanium, tantalum, tantalum nitride, tungsten, platinum, rhodium, molybdenum, cobalt, ruthenium, palladium, or mixtures thereof, or dielectrics like silicon oxide, silicon nitride, aluminum oxide, titanium oxide, other ferroelectric materials, including compositions of hafnium oxide and zirconium oxide, magnetic materials, and mixtures or stacks thereof.

Optionally, substrate 302 can be patterned or textured, as appropriate, with any suitable topography, including flat surfaces, trenches, vias, or nanostructured surfaces. This list represents typical substrates that may be useful in ferroelectric applications, but should not be considered limiting, as many other suitable compositions and surface patterns would be obvious to those skilled in the art. In this regard, it is known that the substrate can have some influence on the atomic arrangement and phase of the film formed thereon, including affecting the crystalline orientation and crystallization temperature of the film.

In other embodiments, a mixed hafnium oxide and zirconium oxide dielectric material is prepared and deposited as a layer. The dielectric material may be prepared and deposited as layer from the vapor by ALD by alternating First Cycle 303 (which includes the steps of (i) pulsing (MeCp)₂Zr(OMe)Me 304, (ii) purging, (iii) pulsing ozone 305 and (iv) purging) and Second Cycle 306 (which includes the steps of (i) pulsing (MeCp)₂Hf(OMe)Me 307, (ii) purging, (iii) pulsing ozone 308 and (iv) purging).

Those skilled in the art will recognize that other precursors, such as (MeCp)₂HfMe₂ and (MeCp)₂ZrMe₂ and other reactants, such as water, hydrogen peroxide or oxygen plasma, may also or alternatively be used. Those skilled in the art will further recognize that the pulsing and purging times can each respectively vary depending on equipment. In one embodiment, pulses last from approximately 2 to approximately 3 seconds followed by a purge of approximately 10 seconds. In another embodiment, pulses last from approximately 10 to approximately 15 seconds followed by a purge of approximately 30 seconds to approximately 60 seconds. In another embodiment, the order in which the precursors are deposited can be reversed.

FIG. 3 illustrates a process 300 of providing a substrate 302, providing a bottom electrode 304, exposing the bottom electrode to Hf and or Zr precursor 306, exposing the bottom electrode to reaction gas 308, repeating 309 steps 306 and 308 to achieve the required thickness of dielectric layer 310, exposing the dielectric layer to a Sr precursor 316, exposing the dielectric material to reaction gas 318, repeating 319 steps 316 and 318 to achieve the required thickness of strontium oxide interlayer 320, providing a top electrode 322, and performing an annealing step 324. In the preferred embodiment, all steps 302 to 324 are performed at a temperature of less than 400 degrees Celsius.

In a preferred embodiment, the annealing is performed in the presence of argon at a pressure of 7 Torr for 10 minutes.

FIG. 4 illustrates another embodiment of a process for preparing and depositing the strontium oxide interlayer materials descried herein. In this embodiment, a hafnium oxide, a zirconium oxide, or a mixed hafnium oxide and zirconium oxide dielectric material is prepared and deposited as a layer with a thickness of approximately 30-60 Å is on a stacked substrate of TiN (which may or may not be in direct contact with the dielectric material), a thermally grown SiO₂ layer and a Si wafer. Layer was formed without further thermal processing or capping.

The process 400 includes providing a substrate 402 of 3 kÅ SiO₂, forming a bottom electrode 404, preferably via ALD, forming an optional interlayer 406 comprising a metal oxynitride, forming a dielectric layer 408, wherein the dielectric layer has a thickness of about 30-60 Å and is formed at a temperature of between 20° and 400° C. The step of forming the dielectric layer 408 may include exposing the bottom electrode to Hf and or Zr precursor and exposing the bottom electrode to reaction gas, and repeating these steps to achieve the required thickness of dielectric layer. Forming the SrO_{X} interlayer 410 includes exposing the dielectric layer to a Sr precursor, exposing the dielectric material to reaction gas, preferably ozone, and repeating the steps to achieve the required thickness of strontium oxide interlayer. A post deposition anneal step 412 is performed for up to an hour at a temperature of up to about 600° C. Forming a top electrode 414 is preferably performed using an ALD process and the top electrode preferably comprises TiN and is about 50 Å thick. A step of patterning and forming a capacitor array 416 is performed. In the preferred embodiment, all steps 402 to 416 are performed at a temperature of less than 600 degrees Celsius.

In certain embodiments, the capacitor can be incorporated into a crossbar array or a memory unit cell. In certain embodiments, the capacitor can be incorporated into a neuromorphic computing chip or a synaptic device such as a synaptic memristor or a synaptic transistor.

An embodiment of a process for preparing and depositing the strontium oxide interlayers descried herein using ALD. The method includes several steps that can be augmented with additional and/or optional steps. Step 1 includes providing a substrate at a deposition temperature of between approximately 265° C. and approximately 500° C., but that is preferably at or around approximately 300° C. (e.g., above approximately 285° C. and at or below approximately 300° C.) and below 340° C. Step 2 includes (i) exposing the substrate to a first precursor containing strontium that does not decompose at the deposition temperature and (ii) purging. Step 3 includes (i) exposing the substrate to a reaction gas containing oxygen and (ii) purging. Step 4 includes (i) exposing the substrate to a second precursor containing strontium that does not decompose at the deposition temperature and (ii) purging. Step 5 includes exposing the substrate to a reaction gas containing oxygen. Optional Step 6 includes repeating Steps 2-5 until a film of strontium oxide of desired thickness is formed on the dielectric material.

The reaction gas containing oxygen of Step 3 and/or Step 5 is preferably ozone. Those skilled in the art will recognize that other reaction gases can be used including those specifically described above (e.g., water, hydrogen peroxide).

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

### Device

The bottom (first) electrode and the top (second) electrode may be metallic or semiconducting electrodes having a thickness to ensure good conduction. In the illustrated embodiment, the top electrode comprises titanium nitride. In other embodiments, the top electrode may comprise any of titanium nitride, tungsten, nickel, ruthenium, platinum, and aluminum. In an illustrated embodiment, 50 nm thick TiN is used.

In the illustrated embodiment, the bottom electrode comprises tungsten. In other embodiments, the top electrode may comprise any of titanium nitride, tungsten, ruthenium, platinum, and aluminum. In the illustrated embodiment, 50 nm thick TiN is used.

In these examples, the SrOx ICL was grown according to the following method:
1. The wafer heats to operating temperature over ten minutes at a spacing of 0.3 in from the reactor showerhead. The pressure in the reactor is throttled to 1 Torr under 3000 sccm total Ar gas flows from multiple introduction points.
2. Sr precursor is pulsed through a bubbler with 120 sccm of carrier gas for a duration of 15 seconds. 400 sccm of carrier gas is co-injected from the top of the monoblock to carry the precursor. 25 sccm of Ar is injected from the center port of the chamber, chamber is throttled to 1 Torr.
3. Chamber is purged from excess Sr gas and reaction byproducts for 20 seconds under a fully open throttle. The total Ar flow rate is 2625 sccm from multiple introduction points. The Sr bubbler line is purged directly to a divert pump under 120 sccm of carrier gas flow.
4. 4% O3 is pulsed for 15 seconds at a flow rate of 800 sccm into a chamber with 925 sccm total mass flow rate, the pressure is throttled to 1 Torr
5. Chamber is purged from excess O3 and reaction byproducts for 15 seconds under a fully open throttle. The total Ar flow rate is 2625 sccm from multiple introduction points to purge the chamber.
6. Steps 2-5 comprise a complete SrOx ICL ALD cycle which can be repeated to achieve an ICL with varied thickness.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

The metallocene precursors were or otherwise can be prepared according to U.S. Pat. No. 8,568,530 the contents of which is incorporated herein in its entirety.

The experiments for both of the following two examples were performed in two ALD systems (metal electrode chamber and dielectric chamber) composed of heated showerhead lids which accommodate 12″ wafers. Wafers are placed on heated pedestals within the ALD systems whereby the wafer surface temperature is controlled. For each experiment, samples were fabricated comprising 300 mm silicon wafers prepared with a thermally grown silicon oxide film of ˜3000 Å. A bottom electrode layer of thermal ALD titanium nitride was grown in the metal chamber to a thickness of ˜50 Å at either 400 or 530 C. Following the bottom electrode layer, an optional metal oxynitride of any composition and thickness can be grown as a bottom ICL (not implemented in current examples but can be covered under patent). Following bottom electrode layer deposition, the wafer is transferred to the dielectric chamber. The dielectric film is prepared by atomic layer deposition (ALD) of 30-100 Å, or 30-80 Å or 30-60 Å of zirconium oxide (ZrO2) directly on the bottom electrode layer at a temperature of 260 C or 300 C (or a range of 250 C-400 C). Following ZrO2 growth a thin strontium oxide interface layer (SrOx ICL) is grown on top of the ZrO2 film with 0.5 to 10 Å 0.5 to 8 Å or 0.5 to 5 Å by alternating Sr(iPr₃Cp)₂ and ozone exposures. Following the SrOx ICL layer, the sample is moved to a thermal annealing chamber in which it is annealed for up to one hour at temperatures up to 600 C. After annealing the sample is returned to the metal chamber for a top electrode deposition of ˜50 Å at 400 C. In example 1 the wafer is cleaved into 45 mm square coupons following the deposition of the top electrode, and subsequent depositions and heat treatments are accomplished using carrier substrates. In example 2, the wafer is cleaved into 45 mm square coupons after all depositions and heat treatments to form the stacks.

Sr(iPr3Cp)2 was obtained from EMD Electronics. The normal temperature of the Sr(iPr3Cp)2 source in all conditions is 155° C. to generate volatility. The gas lines between the Sr container and the ALD chamber were heated along their length up to 180° C. Ozone was generated using an MKS ozone generator and delivered at a concentration of 4%. The ozone was introduced at a flow rate of 800 sccm.

For each step in which the deposition was conducted on a blanket 300 mm format, the pedestal was set to a temperature 5 degrees Celsius higher than the reported sample surface temperature to accommodate for thermal losses between the heated pedestal and the wafer. For cases in which cleaved coupons were placed on a carrier wafer for deposition, a larger thermal offset (30 C-50 C depending on desired temperature) was used. Throughout the entire process, an argon purge flow of 100 sccm was continuously run to protect sensitive interior parts of the chamber.

### Example 1: SrOx Interface Layer on ZrO₂ Grown at 300 C

| | | | Approximate SrOx |
|---|---|---|---|
| | | Sr—O₃ top | thickness based on |
| Wafer | ZrO₂ cycles | cycle(s) | 300 C. GR of 0.645 |
| 1 | 66 | 1 | 0.6 Å |
| 2 | 66 | 1 | 0.6 Å |
| 3 | 66 | 2 | 1.3 Å |
| 4 | 66 | 4 | 2.6 Å |
| 5 | 48 | 1 | 0.6 Å |
| 6 | 48 | 2 | 1.3 Å |

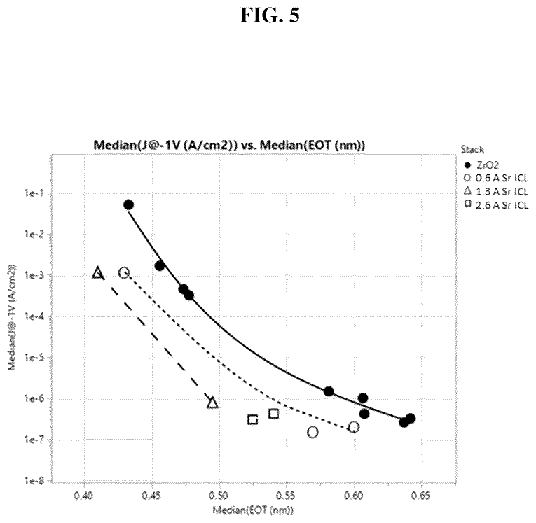

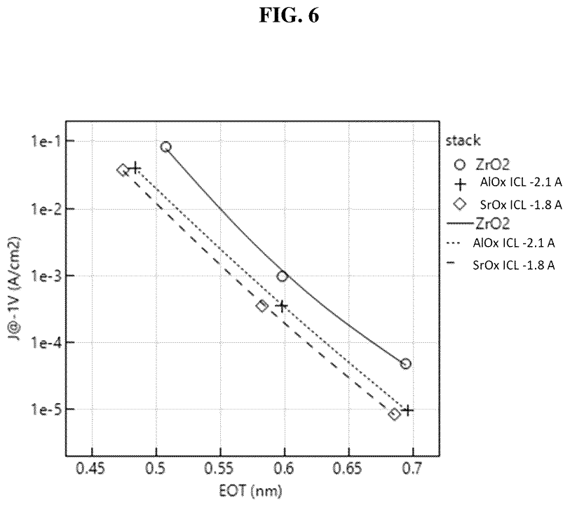

FIG. 5 illustrates Sr-ICL data on dielectric films deposited at 300 C. A marked improvement in LOT is observed for SrOx when deposited as an ICL. Here the 1.3 A Sr ICL shows better performance than 0.6 A or 2.6 A, which implies that there is an optimal Sr ICL thickness.

### Example 2: SrOx Interface Layer on ZrO₂ Grown at 260 C

| | | | | Thickness of ICL |
|---|---|---|---|---|
| | ZrO₂ | ##-O₃ top | | based on 260° C. |
| Wafer | cycles | cycle(s) | Element | GRs (Sr; 0.53; Al 0.9) |
| A | 50 | 0 | (ZrO₂ control) | 0 |
| B | 65 | 0 | (ZrO₂ control) | 0 |
| C | 76 | 0 | (ZrO₂ control) | 0 |
| D | 50 | 4 | Sr | 2.1 Å |
| E | 65 | 4 | Sr | 2.1 Å |
| F | 76 | 4 | Sr | 2.1 Å |
| G | 50 | 2 | Al | 1.8 Å |
| H | 65 | 2 | Al | 1.8 Å |
| I | 76 | 2 | Al | 1.8 Å |

FIG. 6 illustrates ICL data on dielectric films grown at 260° C. Each cluster of points from left to right are of 40,50,60 Å ZrO₂ dielectric films. Each set of symbols comprise three devices with three different ICL conditions. The open circles are reference ZrO₂ devices with no ICL. The crosses are Al₂O₃ ICLs with ˜2 Å thickness. The diamonds are SrOx ICLs with ˜2 Å. Both ICLs show a decrease in leakage current compared to the reference devices, across all thicknesses. At the lowest device thickness, SrOx and Al₂O₃ ICL show improved capacitance (decreased EOT). At 50 and 60 Å film thicknesses, Al₂O₃ ICLs show the same capacitance as ZrO₂ devices. Critically, SrOx ICLs show an improved capacitance relative to both Al₂O₃ ICL and reference ZrO₂ films across all thicknesses.

FIG. 6 show that SrOx top ICL shows a reduction in leakage and a leftward shift in EOT across ZrO₂ thicknesses. The improvement is more apparent in the −1V applied bias case. SrOx outperforms Al₂O₃ when the thickness is equivalent

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

What is claimed is:

1. A capacitor comprising:
a bottom electrode;
a top electrode above the bottom electrode;
a dielectric film between the bottom electrode and the top electrode; and
a SrO_{X} film that forms an interlayer between the top electrode and the dielectric film, wherein X is an integer from 1 to 3.

2. The capacitor of claim 1, wherein the dielectric film comprises ZrO₂, HfO₂, an alloy of ZrO₂ and HfO₂, or combinations thereof.

3. The capacitor of claim 1, wherein the SrOx film has a thickness ranging from about 0.1 Å to about 10.0 Å.

4. The capacitor of claim 1, wherein a further interlayer is provided between the bottom electrode and the dielectric film; and
wherein the further interlayer comprises an oxide of a metal element.

5. The capacitor of claim 1, wherein the bottom electrode directly contacts the dielectric film.

6. The capacitor of claim 1, wherein the dielectric film has a thickness of about 30 Å to about 100 Å; and
wherein the SrO film has a thickness of about 0.1 Å to about 10.0 Å, more preferably from about 0.5 Å to about 5.0 Å.

7. The capacitor of claim 1, wherein the top electrode directly contacts a top surface of the SrOx film, and the dielectric film directly contacts a bottom surface of the SrO_{X} film.

8. The capacitor of claim 1, wherein the top electrode comprises TiN, MoN, CoN, TaN, TiAlN, TaAlN, W, Ru, RuO₂, SrRuO₃, Ir, IrO₂, Pt, PtO, (Ba,Sr)RuO₃ (BSRO), CaRuO₃ (CRO), (La,Sr)CoO₃ (LSCO), or a combination thereof.

9. The capacitor of claim 1, wherein the dielectric film is doped with a metal, wherein the metal is chosen from the group consisting of: Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U.

10. A semiconductor device comprising:
a substrate;
a gate structure on the substrate;
a first source/drain region and a second source/drain region, both arranged in upper portions of the substrate; and
a capacitor on the substrate;
the capacitor comprising a bottom electrode, a top electrode, a dielectric film between the bottom electrode and the top electrode, and a SrO_{X} film between the top electrode and the dielectric film, wherein X is an integer between 1 and 3;
the bottom electrode being electrically connected to the first source/drain region; and
the top electrode being over the bottom electrode.

11. The semiconductor device of claim 10, wherein the SrO_{X} film has a thickness of between about 0.1 Å and about 10 Å, more preferably from about 0.5 Å to about 5.0 Å.

12. A method of fabricating a capacitor comprising:
forming a bottom electrode;
forming a dielectric film;
forming a SrO_{X} layer on the dielectric film, wherein X is an integer from 1 to 3; and
forming a top electrode on the SrO_{X} layer.

13. The method of claim 12, wherein the step of forming the SrO_{X} layer on the dielectric film further comprises a step of performing a heat treatment on the dielectric film and the SrO_{X} layer.

14. The method of claim 12, wherein the forming of the SrO_{X} layer on the dielectric film comprises:
a. arranging a substrate in a reaction chamber and supplying a metal precursor into the reaction chamber;
b. performing a first purging step for removing any excess portion of the introduced metal precursor that is not adsorbed onto the substrate along with any evolved chemical species formed by the reaction of the metal precursor and the substrate;
c. supplying an oxygen-bearing source into the reaction chamber; and
d. performing a second purging for removing the oxygen source that has not reacted with the substrate, along with any evolved chemical species formed by the reaction of the oxygen-bearing gas with the substrate.

15. The method of claim 14, wherein the metal precursor is represented by MR_{X}, wherein M is a metal element and R is an organic ligand; and
X is in a range of 0<x≤6.

16. The method of claim 15, wherein M is Sr; and
wherein R comprises at least one of a C1-C10 alkyl group, a C2-C10 alkenyl group, a carbonyl group (C═O), a halide, a C6-C10 aryl group, a C6-C10 cycloalkyl group, a C6-C10 cycloalkenyl group, (C═O)R (where R is hydrogen or a C1-C10 alkyl group), a C1-C10 alkoxy group, a C1-C10 amidinate, a C1-C10 alkylamide, a C1-C10 alkylimide, N(Q)(Q′) (where Q and Q′ are each independently a C1-C10 alkyl group or hydrogen), Q(C═O)CN (where Q is hydrogen or a C1-C10 alkyl group), and a C1-C10 β-diketonate.

17. The method of claim 16, wherein M is Sr, and wherein the metal precursor is chose from the group consisting of: Sr(i-Pr₃Cp)₂, Sr(t-Bu₃Cp)₂, Sr(Me₅Cp)₂, Sr(n-PrMe₄Cp)₂, bis(2,5-di-iso-propylpyrrolyl)strontium, bis(2,5-di-tert-butylpyrrolyl)strontium, bis(2,4,5-tri-tert-butylimidazolyl)strontium, bis(2,2-dimethyl-5-(dimethylaminoethyl-imino)-3-hexanonato-N,O,N′)strontium, bis(2,2-dimethyl-5-(dimethylaminoethyl-imino)-3-hexanonato-N,O,N′)strontium and their adducts with neutral coordinating ligands.

18. The method of claim 12, wherein the step of forming a SrO_{X} layer on the dielectric film comprises:
a) chemisorbing a strontium precursor on a dielectric material in an atomic layer deposition process;
b) reacting an oxygen source with the chemisorbed strontium precursor;
c) repeating a cycle of chemisorbing the strontium precursor and reacting the oxygen source with the chemisorbed strontium precursor for a number of cycles to form a strontium oxide material on the dielectric material; and
d) annealing the strontium oxide material to form the strontium oxide layer.

19. The method of claim 18, wherein repeating the cycle of chemisorbing the strontium precursor and reacting the oxygen source with the chemisorbed first strontium precursor until a desired thickness of the strontium oxide material is formed comprises a desired thickness of at least approximately 1.0 Å and no more than 10.0 Å.

20. The method of claim 18, wherein the step of repeating the cycle of chemisorbing the strontium precursor and reacting the oxygen source with the chemisorbed strontium precursor for between one and four cycles to form a desired thickness of the strontium oxide material.
